(19) United States
(12) Patent Application Publication
(10) Pub. No.: US 2024/0038953 A1
(43) Pub. Date: Feb. 1, 2024

(54) DISPLAY DEVICE

(71) Applicant: KYOCERA Corporation, Kyoto-shi, Kyoto (JP)

(72) Inventors: Sho NAKAMITSU, Kusatsu-shi, Shiga (JP); Hiroaki ITO, Ritto-shi, Shiga (JP)

(21) Appl. No.: 18/265,793

(22) PCT Filed: Dec. 1, 2021
(86) PCT No.: PCT/JP2021/044085

§ 371 Date: Jun. 7, 2023

(30) Foreign Application Priority Data
Dec. 8, 2020 (JP) 2020-203724

(51) Int. Cl. H01L 33/62; H01L 25/075; G09G 3/00

(52) U.S. Cl. CPC H01L 33/62; H01L 25/0753; G09G 3/006; G09G 2330/12

(57) ABSTRACT

A display device includes a substrate including a first surface, a side surface, and a second surface opposite to the first surface, a display on the first surface, an electrode pad on the second surface and electrically connected to the display, an external connection terminal on the second surface, a first wire on the second surface and electrically connecting the electrode pad and the external connection terminal, and an inspection pad on the second surface and electrically connected to the electrode pad. At least a central portion of the inspection pad does not overlap the first wire.

### TECHNICAL FIELD

The present disclosure relates to a display device such as a light-emitting diode (LED) display device including light emitters such as LEDs.

### BACKGROUND OF INVENTION

A known display device is described in, for example, Patent Literature 1.

### CITATION LIST

### Patent Literature

Patent Literature 1: Japanese Unexamined Patent Application Publication No. 2008-134073

### SUMMARY

A display device according to an aspect of the present disclosure includes a substrate including a first surface, a side surface, and a second surface opposite to the first surface, a display on the first surface, an electrode pad on the second surface and electrically connected to the display, an external connection terminal on the second surface, a first wire on the second surface and electrically connecting the electrode pad and the external connection terminal, and an inspection pad on the second surface and electrically connected to the electrode pad, and at least a central portion of the inspection pad not overlapping the first wire.

A display device according to an aspect of the present disclosure includes a substrate including a first surface, a side surface, and a second surface opposite to the first surface, a display on the first surface, an electrode pad on the second surface and electrically connected to the display, a side wire extending from the first surface through the side surface to the second surface and electrically connecting the display and the electrode pad, and an inspection pad on the side surface and electrically connected to the side wire, and at least a central portion of the inspection pad not overlapping the side wire.

### BRIEF DESCRIPTION OF THE DRAWINGS

The objects, features, and advantages of the present disclosure will become more apparent from the following detailed description and the drawings.

FIG. 1 is a plan view of a display device according to one embodiment of the present disclosure illustrating its circuit structure.

FIG. 2 is a plan view of the display device according to the embodiment of the present disclosure illustrating its circuit structure, as viewed in a direction opposite to the direction in FIG. 1.

FIG. 3 is a partial cross-sectional view of the display device according to the embodiment of the present disclosure.

FIG. 4 is a plan view of the display device according to the embodiment of the present disclosure, illustrating a main part of its circuit structure.

FIG. 5 is a plan view of the display device according to the embodiment of the present disclosure, illustrating a main part of its circuit structure.

FIG. 6 is a plan view of a display device according to another embodiment of the present disclosure, illustrating a main part of its circuit structure.

FIG. 7 is a plan view of a display device according to another embodiment of the present disclosure, illustrating a main part of its circuit structure.

FIG. 8 is a plan view of a display device according to another embodiment of the present disclosure, illustrating a main part of its circuit structure.

FIG. 9 is a plan view of a display device according to another embodiment of the present disclosure, illustrating a main part of its circuit structure.

FIG. 10 is a plan view of a display device according to another embodiment of the present disclosure, illustrating a main part of its circuit structure.

FIG. 11 is a plan view of a display device according to another embodiment of the present disclosure illustrating its circuit structure.

FIG. 12 is a plan view of the display device according to the other embodiment of the present disclosure illustrating its circuit structure, as viewed in a direction opposite to the direction in FIG. 11.

FIG. 13A is an enlarged plan view of an inspection pad in the circuit structure in FIG. 6.

FIG. 13B is an enlarged plan view of the inspection pad in the circuit structure in FIG. 6 in another embodiment.

FIG. 13C is an enlarged plan view of the inspection pad in the circuit structure in FIG. 6 in another embodiment.

FIG. 13D is an enlarged plan view of the inspection pad in the circuit structure in FIG. 6 in another embodiment.

FIG. 14 is an enlarged plan view of the inspection pad in the circuit structure in FIG. 6 in another embodiment.

FIG. 15 is a partial plan view of a display device according to another embodiment of the present disclosure, illustrating its main part.

FIG. 16 is a partial side view of the display device in FIG. 15, illustrating the main part.

FIG. 17 is a partial cross-sectional view of the display device in FIG. 15, illustrating the main part.

### DESCRIPTION OF EMBODIMENTS

The structure that forms the basis of a display device according to one or more embodiments of the present disclosure will now be described. Various liquid crystal display devices including a liquid crystal panel and a backlight and various self-luminous display devices including light emitters such as light-emitting diodes (LEDs) have been developed. Such display devices are inspected before shipment to detect display defects. Patent Literature 1 describes inspection of a display device performed by placing an inspection element in an inspection unit into contact with an inspection pad on the display device, providing an inspection signal from the inspection element in the inspection unit to the inspection pad, and observing the light emission of the display device.

Techniques are known for fabricating a composite large display device (hereafter also referred to as a multi-display) including multiple display devices connected (tiled) together. Known display devices include inspection pads in their peripheral areas (frame portions) surrounding a display area. Display devices in a multi-display thus cannot easily reduce the size of the frame portions. In such a multi-display, the boundaries (frame portions) between the display devices may appear black.

Additionally, a pixel (pixel a) nearest the frame portion surrounding a display in a first display device and a pixel (pixel b) nearest the frame portion surrounding a display in a second display device adjacent to the first display device, or a pixel adjacent to the pixel a, has a pixel pitch between them larger than the pixel pitch between pixels located in the display portions outside the frame portions. In other words, the multi-display can have variations in the pixel pitch at the boundaries (frame portions) between the display devices, and thus can have a periodically nonuniform pixel pitch. This may cause discomfort to a viewer viewing images.

Inspection pads may be arranged on a non-display surface (rear surface) of the display device to allow the frame portion to be narrower without being restricted by the inspection pads. However, the inspection pads on the rear surface cannot be easily reached by an inspection element such as a terminal probe. The inspection element may be pressed against, for example, electrode pads, wiring conductors, and external connection terminals located adjacent to inspection pads and damage, for example, such electrode pads or wiring conductors.

The display device according to one or more embodiments of the present disclosure will now be described with reference to the accompanying drawings. Each figure referred to below illustrates main components and other elements of the display device according to one or more embodiments. In the present embodiment, the display device may include known components that are not illustrated, for example, circuit boards, wiring conductors, control integrated circuits (ICs), and control LSI circuits. The figures referred to below are schematic, and the positions and the scale of the components of the display device may be imprecise.

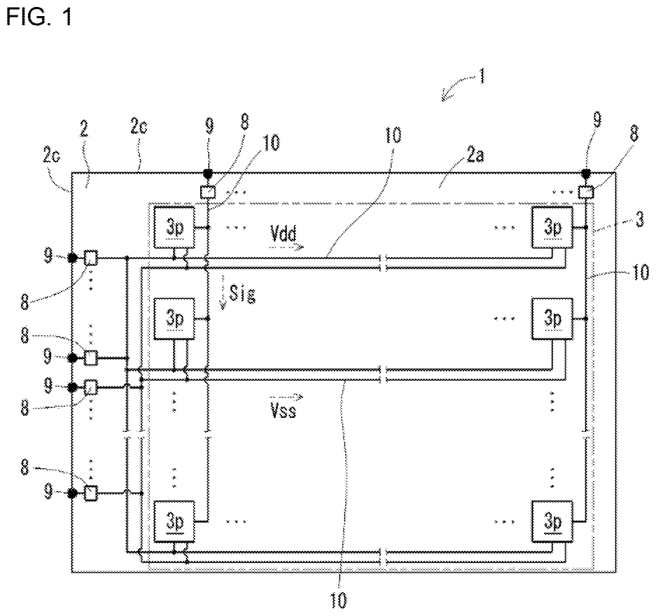

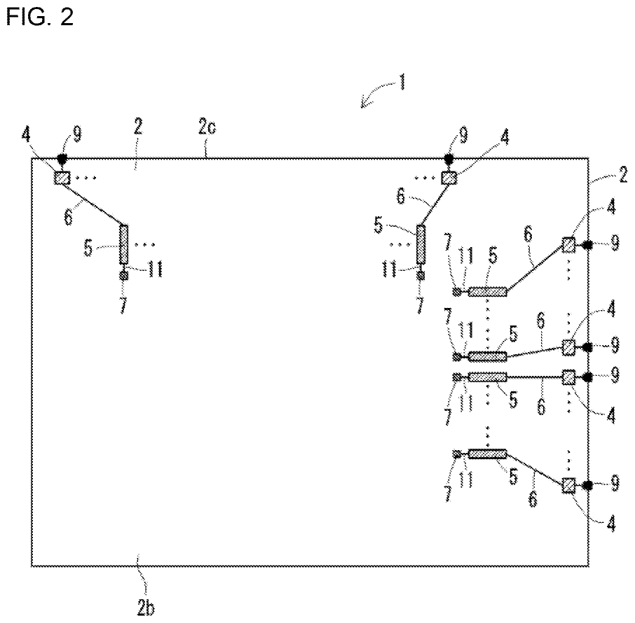

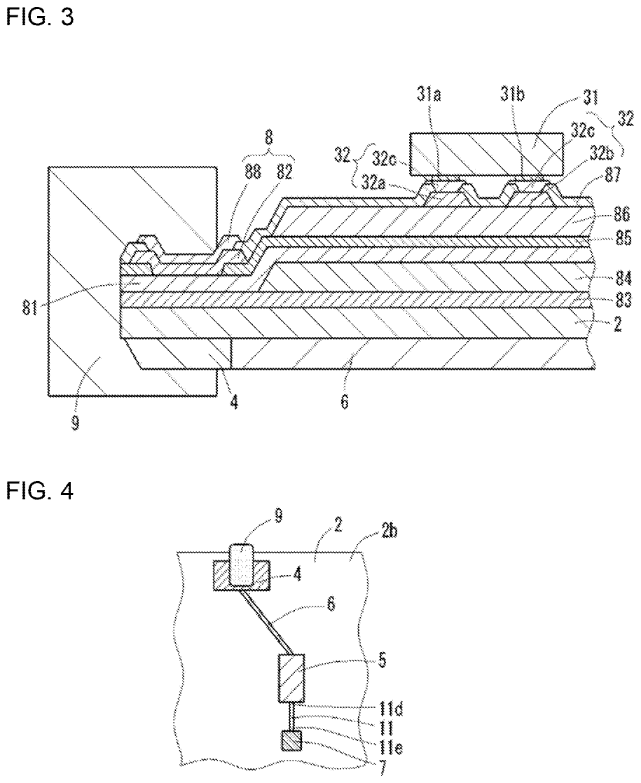

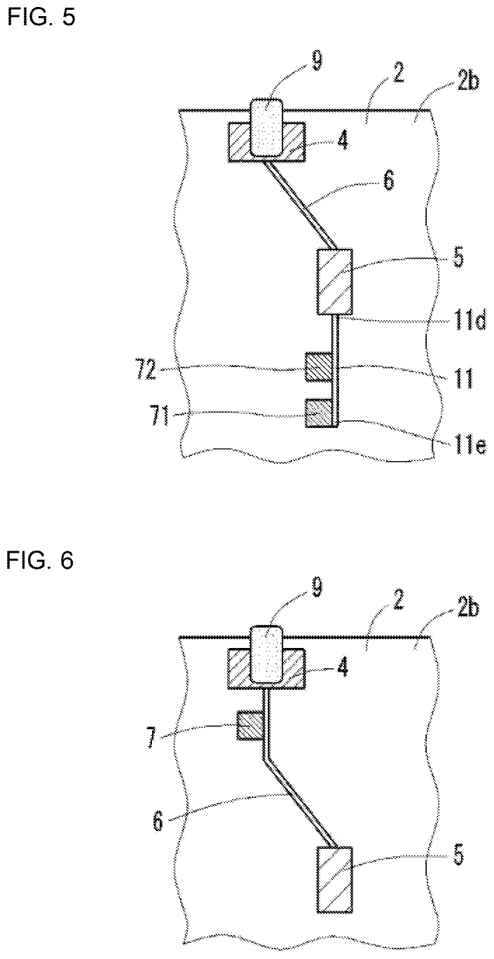

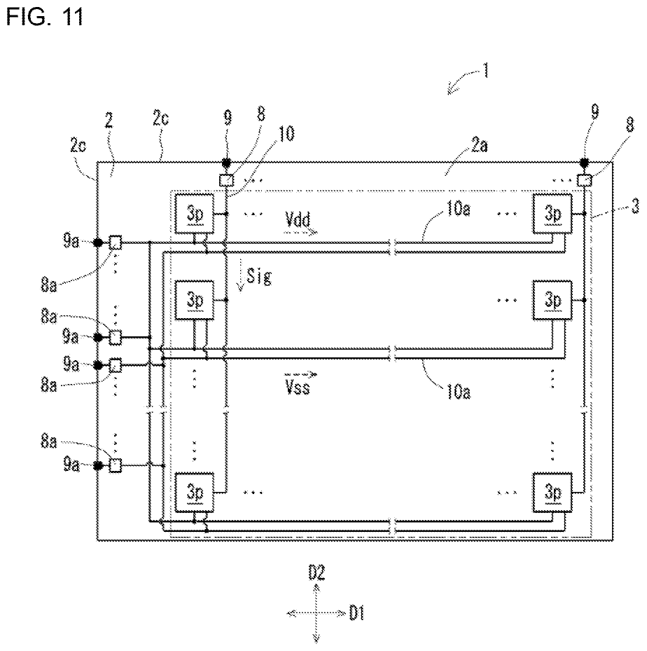

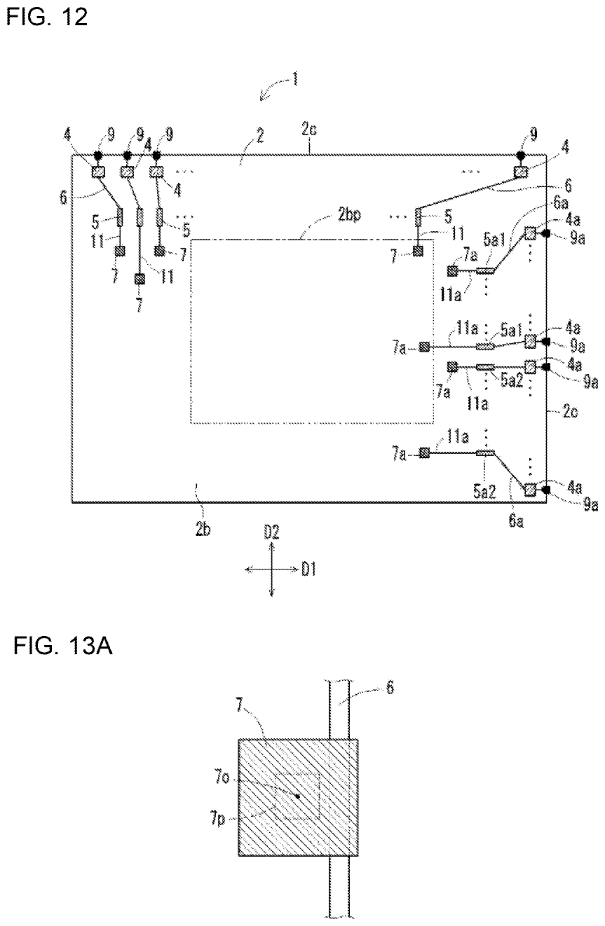

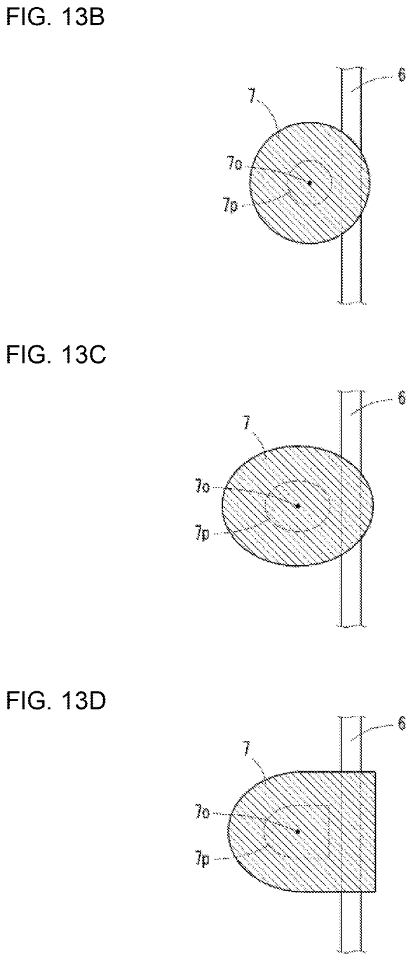

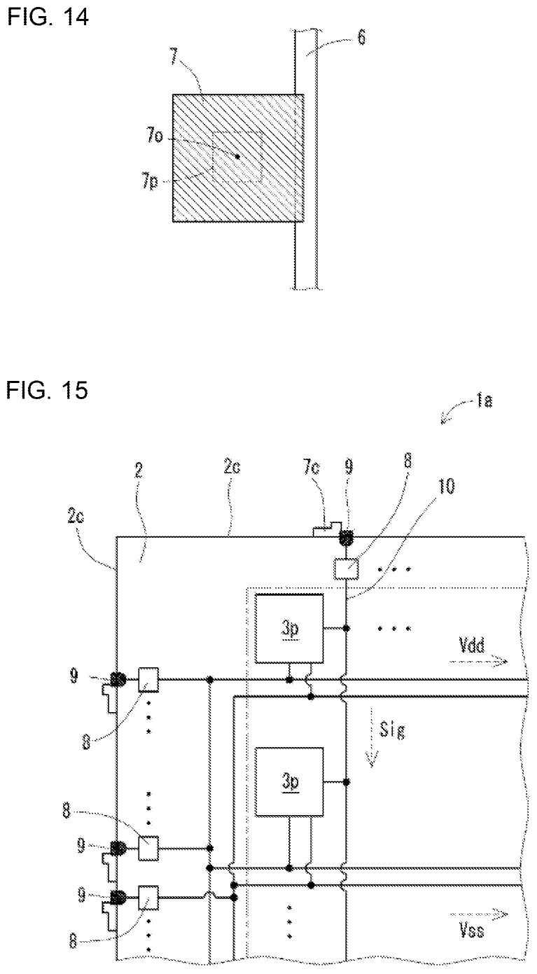

FIGS. 1 and 2 are diagrams of a display device according to one embodiment of the present disclosure illustrating its circuit structure. FIG. 3 is a cross-sectional view of the display device according to the embodiment of the present disclosure. FIGS. 4 and 5 are diagrams of the display device according to the embodiment of the present disclosure, illustrating a main part of its circuit structure. FIGS. 6 to 10 are diagrams of a display device according to another embodiment of the present disclosure, illustrating a main part of its circuit structure. FIGS. 11 and 12 are diagrams of a display device according to another embodiment of the present disclosure illustrating its circuit structure. FIGS. 13A to 13D and 14 are enlarged views of an inspection pad in the circuit structure in FIG. 6. FIGS. 1 and 11 are plan views of the display device as viewed from above a first surface of a substrate. FIGS. 2 and 12 are plan views of the display device as viewed from a second surface of the substrate. The first surface is a front surface and also a display surface. The second surface is a rear surface and also a non-display surface. FIG. 3 is a partial cross-sectional view of a portion including the periphery of the substrate. FIGS. 4 to 10 are plan views of the display device as viewed from above the second surface of the substrate. FIGS. 4 to 10 each illustrate an electrode pad, an external connection terminal, the inspection pad, and a side wire with hatching for ease of illustration. FIGS. 13A to 13D and 14 are plan views of the substrate as viewed from above the second surface. FIGS. 13A to 13D and 14 each illustrate the inspection pad with hatching for ease of illustration.

In one or more embodiments of the present disclosure, a display device 1 includes a substrate 2, a display 3, electrode pads 4, external connection terminals 5, first wires 6, and inspection pads 7. The display 3 includes multiple pixel units 3p that are arranged in a matrix.

In one or more embodiments of the present disclosure, the display device 1 includes the substrate 2 including a first surface 2a, side surfaces 2c, and a second surface 2b opposite to the first surface 2a, the display 3 on the first surface 2a, the electrode pads 4 on the second surface 2b electrically connected to the display 3, external connection terminals 5 on the second surface 2b, the first wires 6 on the second surface 2b electrically connecting the electrode pads 4 and the external connection terminals 5, and the inspection pads 7 on the second surface 2b electrically connected to the electrode pads 4. Each inspection pad 7 is positioned with at least a central portion 7p (illustrated in FIGS. 13A and 14) not overlapping any first wire 6.

In one or more embodiments of the present disclosure, the display device 1 with the above structure produces the effects described below. With the inspection pads 7 on the non-display surface, the display device 1 can reduce the size of the frame portion or include no frame portion. This reduces the visibility of the boundary portions between the display devices 1 in a multi-display to the viewer. This also reduces variations in the pixel pitch at the boundaries between display devices, thus easily achieving a uniform pixel pitch. The multi-display can thus have higher image quality and have high definition. Each inspection pad 7 is positioned on the second surface 2b with at least its central portion 7p not overlapping any first wire 6. This reduces the likelihood that an inspection member such as an inspection terminal probe comes in contact with or is pressed against, for example, the electrode pads, the wiring conductors, and the external connection terminal 5 adjacent to the inspection pads 7 and damage these components. The display device 1 can thus be manufactured with a higher yield.

Th electrode pads (also referred to as first electrode pads) 4 may be relay electrode pads for relaying signals for controlling the display 3, such as scanning signals, image signals, and power supply voltage signals, to the display 3. The electrode pads 4 may be electrode pads for side wire connection connectable to side wires 9. Each electrode pad 4 may have one of various shapes, including a quadrangle such as a square or a rectangle, a circle, an oval, an ellipse, and a polygon such as a pentagon.

The inspection member may be a thin-rod inspection probe such as an inspection terminal probe or an inspection terminal, or may be an inspection tool with, for example, protruding inspection electrode pads that can come in contact with the multiple inspection pads 7 at a time.

As illustrated in each of FIGS. 13A to 13D, the inspection pad 7 may include a peripheral portion overlapping the first wire 6 outside the central portion 7p. In this structure, the inspection pad 7 is directly connected to the first wire 6. This reduces connection resistance between the inspection pad 7 and the first wire 6, thus allowing accurate inspection with the inspection pad 7. This also reduces the area to be used by the inspection pad 7, thus easily allowing the side wires 9 and the first wires 6 to be arranged with smaller pitches.

As illustrated in FIG. 14, the inspection pad 7 may include an edge that is linearly in contact with the first wire 6. In this structure, the inspection pad 7 is directly connected to the first wire 6. This reduces connection resistance between the inspection pad 7 and the first wire 6, thus allowing accurate inspection with the inspection pad 7. This also reduces the likelihood that an inspection member such as a terminal probe comes in contact with or is pressed against the first wire 6 adjacent to the inspection pad 7 and damages the first wire 6. In the above structure, the inspection pad 7 that is linearly in contact with the first wire 6 refers to the inspection pad 7 having its narrow edge overlapping a narrow edge of the first wire 6, as illustrated in FIG. 14. The edges that are linearly in contact with each other may have, but are not limited to, a width of about 1 to 100 μm. A range of values referred to herein as one value to another value intends to mean the two values being inclusive.

An area of the central portion 7p of the inspection pad 7 may be at least 10% of the area of the inspection pad 7. When the central portion 7p has the area less than 10%, the first wire 6 is adjacent to a center 7o of the inspection pad 7 that comes in contact with or is pressed against the inspection member and may be damaged by the inspection member. The inspection member may come in contact with or is pressed against a larger area including the center 7o of the inspection pad 7. When the central portion 7p of the inspection pad 7 has an area of 10% or more of the area of the inspection pad 7, the first wire 6 is not too close to the center 7o. This reduces the likelihood of the inspection member damaging the first wire 6. The ratio of the area of the central portion 7p to the area of the inspection pad 7 may be up to, for example, about 70%, about 60%, about 50%, or any other ratio.

As illustrated in FIG. 13B, the inspection pad 7 may be circular, and the central portion 7p of the inspection pad 7 may also be circular. This reduces the area of the inspection pad 7 and also facilitates inspection with the inspection pad 7 and the central portion 7p having a shape similar to the shape of the tip of the inspection terminal probe.

As illustrated in FIG. 13C, the inspection pad 7 may have an oval shape elongated in the lateral direction (a direction orthogonal to the direction in which the first wire 6 extends), and the central portion 7p of the inspection pad 7 may have the same or similar oval shape. This allows the inspection pad 7 to have a relatively small area and also facilitates inspection with the inspection pad 7 and the central portion 7p having the shape substantially similar to the shape of the tip of the inspection terminal probe.

As illustrated in FIG. 13D, the inspection pad 7 may have a semicircular shape elongated in the lateral direction (direction orthogonal to the direction in which the first wire 6 extends) or the shape of a half-racetrack, and the central portion 7p of the inspection pad 7 may have the same or similar semicircular shape or a similar shape of a half-racetrack. This allows the inspection pad 7 to have a relatively small area and also allows the area of connection between the inspection pad 7 and the first wire 6 to be large, as in or similarly to the structure in FIG. 13A. This also facilitates inspection with the inspection pad 7 and the central portion 7p having the shape relatively similar to the shape of the tip of the inspection terminal probe.

The central portion 7p of the inspection pad 7 may have a shape similar to the shape of the inspection pad 7, or may have a shape similar to the shape of the tip of the inspection terminal probe as an inspection member, such as a circular or oval shape. This reduces the likelihood that the tip of the inspection terminal probe comes in contact with a point outside the central portion 7p when the inspection terminal probe comes in contact with the central portion 7p of the inspection pad 7. To effectively achieve this, the central portion 7p of the inspection pad 7 may have an area not smaller than the area of the tip of the inspection terminal probe. The central portion 7p of the inspection pad 7 may have an area larger than the area of the tip of the inspection terminal probe. The central portion 7p of the inspection pad 7 may have, but is not limited to, an area larger than the area of the tip of the inspection terminal probe and not larger than about 10 times the area of the tip of the inspection terminal probe.

As illustrated in FIGS. 2, 4, 5, 9, 10, and 12, no portion of each the inspection pad 7 overlaps the first wire 6. This reliably reduces the likelihood that the inspection member comes in contact with or is pressed against and damages any first wire 6.

The substrate 2 is, for example, a transparent or opaque glass substrate, a plastic substrate, or a ceramic substrate. The substrate 2 includes the first surface 2a, the second surface 2b opposite to the first surface 2a, and the side surfaces 2c connecting the first surface 2a and the second surface 2b. The substrate 2 may be a composite substrate including multiple substrates made of different materials stacked on one another. The substrate 2 may be a flexible substrate, such as a thin flexible plastic substrate.

The substrate 2 may be a triangular plate, a rectangular plate, a trapezoidal plate, a pentagonal plate, a hexagonal plate, a circular plate, an oval plate, or a plate with any other shape. The substrate 2 being, for example, an equilateral triangular plate, a rectangular plate, or a regular hexagonal plate facilitates tiling of multiple display devices 1 into a multi-display. In the present embodiment, the substrate 2 is a rectangular plate.

The pixel units 3p are arranged, for example, in a matrix on the first surface 2a. Each pixel unit 3p includes a light emitter 31 and an electrode pad 32. Each pixel unit 3p further includes a drive circuit for driving and controlling the light emitter 31. The drive circuit may include a thin-film transistor (TFT) and a capacitor. The TFT may include a semiconductor film (or a channel) of, for example, amorphous silicon (a-Si) or low-temperature polycrystalline silicon (LTPS). The TFT may include three terminals, or specifically, a gate electrode, a source electrode, and a drain electrode. The TFT serves as a switching element that switches conduction and non-conduction between the source electrode and the drain electrode based on the voltage applied to the gate electrode. The drive circuit may be formed using a thin film formation method such as chemical vapor deposition (CVD).

Each light emitter 31 may be, for example, a self-luminous light emitter such as an LED, an organic electroluminescent (OEL) element, or a semiconductor laser diode (LD) element. In the present embodiment, the light emitter 31 is an LED that is a two-terminal element including an anode electrode 31a and a cathode electrode 31b. The light emitter 31 may be a micro-LED. The light emitter 31 being a micro-LED located on the first surface 2a may be rectangular in a plan view with each side having a length of about 1 to 100 μm inclusive or about 3 to 10 m inclusive.

The electrode pad 32 connected to the light emitter 31 to provide drive signals to the light emitter 31 is located on the first surface 2a of the substrate 2. The electrode pad 32 includes an anode pad 32a and a cathode pad 32b. The anode pad 32a and the cathode pad 32b are made of a conductive material. The anode pad 32a and the cathode pad 32b may each include a single metal layer, or multiple metal layers stacked on one another. The anode pad 32a and the cathode pad 32b may include layers of, for example, Mo/Al/Mo or MoNd/AlNd/MoNd. The stack of Mo/Al/Mo includes a Mo layer, an Al layer, and a Mo layer in this order. The same applies to other notations. MoNd is an alloy of Mo and Nd. The same applies to other notations. The anode pad 32a and the cathode pad 32b may include surfaces coated with a transparent conductive layer 32c of, for example, indium tin oxide (ITO) or indium zinc oxide (IZO).

The anode electrode 31a of the light emitter 31 is electrically connected to the anode pad 32a of the electrode pad 32. The cathode electrode 31b of the light emitter 31 is electrically connected to the cathode pad 32b of the electrode pad 32. The anode electrode 31a may be electrically connected to the anode pad 32a, and the cathode electrode 31b may be electrically connected to the cathode pad 32b, each with a conductive bond such as a conductive adhesive or solder.

The pixel unit 3p may include multiple light emitters 31, multiple anode pads 32a, and a cathode pad 32b. The multiple anode pads 32a are electrically connected to the anode electrodes 31a of the respective light emitters 31. The cathode pad 32b is a common cathode pad to which the cathode electrodes 31b of the multiple light emitters 31 are electrically connected commonly. The multiple light emitters 31 included in one pixel unit 3p may include a red light emitter that emits red light, a green light emitter that emits green light, and a blue light emitter that emits blue light. This allows the pixel unit 3p to display full-color gradation. The pixel unit 3p may include, in place of the red light emitter, a light emitter that emits orange, red-orange, red-violet, or violet light. The pixel unit 3p may include, in place of the green light emitter, a light emitter that emits yellow-green light.

The electrode pads 4 are located on the second surface 2b. The electrode pads 4 may be located at the periphery of the second surface 2b in a plan view. The periphery may have a width of about 30 to 150 μm. The electrode pads 4 are electrically connected to the pixel units 3p on the first surface 2a. The electrode pads 4 may be electrically connected to TFTs included in the pixel units 3p, or may be electrically connected to the anode pads 32a or the cathode pads 32b.

The electrode pads 4 are made of a conductive material. Each electrode pad 4 may include a single metal layer, or multiple metal layers stacked on one another. The electrode pads 4 may include layers of, for example, Al, Al/Ti, Ti/Al/Ti, Mo, Mo/Al/Mo, MoNd/AlNd/MoNd, Cu, Cr, Ni, or Ag. In the example of FIG. 3, the electrode pad 4 includes a single metal layer formed on the second surface 2b. The electrode pads 4 may be partially covered with an overcoat layer (not illustrated) of, for example, SiO₂, Si₃N₄, or a polymeric material such as an acrylic resin.

The external connection terminals 5 are located on the second surface 2b. The external connection terminals 5 may be electrode pads for providing emission control signals Sig to the pixel units 3p or may be electrode pads for providing a power supply voltage to the pixel units 3p. The emission control signals Sig control the luminance of the pixel units 3p. The power supply voltage may be a first power supply voltage Vdd provided to the anode electrodes 31a of the light emitters 31 or may be a second power supply voltage Vss lower than the first power supply voltage Vdd and provided to the cathode electrodes 31b of the light emitters 31. The external connection terminals 5 are connectable to a circuit board that outputs the emission control signals Sig or the power supply voltages Vdd and Vss provided to the pixel units 3p. The circuit board may be a flexible printed circuit (FPC) board including a drive element such as an IC for driving and controlling the pixel units 3p and circuit wiring.

The external connection terminals 5 are made of a conductive material. The external connection terminals 5 may be made of the same or similar material and may have the same or similar layer structure as the electrode pads 4 described above.

The first wires 6 are located on the second surface 2b. Each first wire 6 connects the electrode pad 4 and the external connection terminal 5. In a plan view, the first wires 6 may linearly connect the electrode pads 4 and the external connection terminals 5 or may each have one or more bends.

The first wires 6 are made of a conductive material. The first wires 6 may be made of the same or similar material and may have the same or similar layer structure as the electrode pads 4 described above. The first wires 6 may be at least partially covered with an overcoat layer (not illustrated) of, for example, SiO₂, Si₃N₄, or a polymeric material such as an acrylic resin.

At least one inspection pad 7 is located on the second surface 2b. The inspection pad 7 is electrically connected to an electrode pad 4 and is electrically connected to a pixel unit 3p with the electrode pad 4. The inspection pad 7 is in contact with the inspection member included in an inspection apparatus for inspecting the display device 1.

For example, the display device 1 may be inspected in the manner described below. An inspection signal output from the inspection apparatus is input into the inspection pad 7. The inspection signal input into the inspection pad 7 is input into the pixel unit 3p through the electrode pad 4. The inspection is then performed by determining whether the pixel unit 3p has, for example, the luminance corresponding to the inspection signal. The inspection may also be performed as described below. A drive signal from a drive element connected to an external connection terminal 5 is input into the pixel unit 3p through the first wire 6 and the electrode pad 4. The inspection member is placed in contact with the inspection pad 7 to detect the drive signal transmitted through the first wire 6. The inspection is then performed by determining whether the drive signal has a predetermined strength (level), frequency, and timing and whether the pixel unit 3p has, for example, the luminance corresponding to the drive signal.

The inspection pads 7 are made of a conductive material. The inspection pads 7 may be made of the same or similar material and may have the same or similar layer structure as the electrode pads 4 described above. The inspection pads 7 may have one of various shapes, including a triangle, a rectangle, a trapezoid, a circle, an oval, and a polygon such as a pentagon in a plan view.

The inspection pads 7 may be electrically connected to the electrode pads 4. In other words, the inspection pads 7 may be directly connected to the electrode pads 4, the external connection terminals 5, or the first wires 6. The inspection pads 7 may be connected to the electrode pads 4, the external connection terminals 5, or the first wires 6 with second wires 11 on the second surface 2b. In the present embodiment, the inspection pads 7 are connected to the external connection terminals 5 with the second wires 11 as illustrated in, for example, FIGS. 2 and 4.

The second wires 11 may be made of the same or similar material as the electrode pads 4 described above and may have the same or similar layer structure as the electrode pads 4 described above. In a plan view, the second wires 11 may linearly connect the inspection pads 7 and the external connection terminals 5 or may each have one or more bends.

The display device 1 may include an emission control signal line that can be inspected using an input inspection signal simulating an emission control signal Sig into each inspection pad 7. The display device 1 may also include a power supply voltage line that can be inspected using an input inspection signal simulating the first power supply voltage Vdd or the second power supply voltage Vss into each inspection pad 7.

As illustrated in, for example, FIG. 3, the display device 1 may include other electrode pads (also referred to as second electrode pads) 8 located on the first surface 2a and electrically connected to the display 3, and side wires 9 extending from the first surface 2a to the second surface 2b through the side surfaces 2c and connecting the first electrode pads 4 and the second electrode pads 8.

The second electrode pads 8 are electrically connected to the pixel units 3p in the display 3. The second electrode pads 8 may be located at the periphery of the first surface 2a in a plan view. The periphery may have a width of about 30 to 150 μm.

The second electrode pads 8 are made of a conductive material. The second electrode pads 8 may be made of the same or similar material and may have the same or similar layer structure as the electrode pads 4 described above. In the example of FIG. 3, the second electrode pad 8 includes a metal layer 82 and a metal layer 88 stacked on each other and is located on insulating layers 83 and 84 on the first surface 2a. The second electrode pad 8 also includes a rear surface connected to a connection wire 81 electrically connected to, for example, a TFT and the light emitter 31.

As illustrated in, for example, FIG. 3, the second electrode pad 8 including the metal layers 82 and 88 stacked on each other may include an insulating layer 87 partly between the metal layers 82 and 88. The second electrode pad 8 may include insulating layers 85 and 86 on its inward end (right in FIG. 3). This reduces the likelihood of short-circuiting between the second electrode pad 8 and a wiring conductor or another element located inward. The insulating layers 83, 84, 85, 86, and 87 are made of, for example, SiO₂, Si₃N₄, or a polymeric material such as an acrylic resin. The metal layer 88 nearer the surface of the second electrode pad 8 may be a transparent conductive layer of, for example, ITO or IZO.

As illustrated in FIG. 1, the second electrode pads 8 may be electrically connected to the pixel units 3p with, for example, a first conductor pattern 10 on the first surface 2a. The first conductor pattern 10 may include, for example, layers of Mo/Al/Mo or MoNd/AlNd/MoNd. The first conductor pattern 10 may include scanning signal lines, image signal lines, or emission control signal lines connecting the TFTs included in the pixel units 3p and the second electrode pads 8. The first conductor pattern 10 may include power supply wires connecting the anode pads 32a or the cathode pads 32b to the second electrode pads 8. The first conductor pattern 10 may include the anode pads 32a or the cathode pads 32b connected to the first conductor pattern 10. The first conductor pattern 10 may be a linear conductor pattern or a planar conductor pattern. For example, the first conductor pattern 10 including power supply wires for the power supply voltage Vss connecting the cathode pads 32b to the second electrode pads 8 may be a planar conductor pattern.

The side wires 9 extend from the first surface 2a to the second surface 2b through the side surfaces 2c. The side wires 9 connect the second electrode pads 8 on the first surface 2a and the first electrode pads 4 on the second surface 2b.

The side wires 9 may include a conductive paste containing conductive particles of, for example, Ag, Cu, Al, or stainless steel, an uncured resin component such as an epoxy resin, an alcohol solvent such as ethyl alcohol, and water. The conductive paste may be applied to an intended portion from the side surfaces 2c to the first surface 2a and to the second surface 2b and cured by heating, photocuring using ultraviolet ray irradiation, or a combination of photocuring and heating. The side wires 9 may also be formed with a thin film formation method such as plating, vapor deposition, or CVD. The side surfaces 2c may include grooves formed in advance for the side wires 9. This allows the conductive paste for the side wires 9 to be easily received in the intended portions on the side surfaces.

When the first electrode pads 4 are located at the periphery of the second surface 2b in a plan view, and the second electrode pads 8 are located at the periphery of the first surface 2a in a plan view, the first electrode pads 4 and the second electrode pads 8 may overlap each other in a plan view. This reduces the length of the side wires 9 connecting the first electrode pads 4 and the second electrode pads 8, thus reducing resistance. This also reduces the likelihood of short-circuiting caused by any side wire 9 coming in contact with, for example, another wiring pad or another wiring conductor in the display device 1.

The first electrode pads 4 and the second electrode pads 8 can be connected with feedthrough conductors, such as through-holes, extending through the substrate 2 from the first surface 2a to the second surface 2b. To connect the first electrode pads 4 and the second electrode pads 8 with feedthrough conductors, for example, the substrate 2 is to have edge areas for the feedthrough conductors and thus cannot easily have a frame portion with a smaller area. With the first electrode pads 4 and the second electrode pads 8 connected to each other with the side wires 9, the display device 1 can easily have a frame portion with a smaller area.

The side wires 9 may be covered with an overcoat layer of, for example, SiO₂, Si₃N₄, or a polymeric material such as an acrylic resin. The side wires 9 in this structure are protected with the overcoat layer and are less likely to be, for example, damaged, chipped, and peeled. The overcoat layer may be made of a photocuring or a thermosetting resin material containing a light-absorbing material (light-shielding material). The light-absorbing material may be, for example, an inorganic pigment. The inorganic pigment may be, for example, a carbon pigment such as carbon black, a nitride pigment such as titanium black, or a metal oxide pigment such as a Cr—Fe—Co, Cu—Co—Mn, Fe—Co—Mn, or Fe—Co—Ni—Cr pigment.

The inspection pads 7 may be connected to the external connection terminals 5 with the second wires 11 on the second surface 2b as illustrated in, for example, FIGS. 2 and 4. Each second wire 11 may include one end 11d connected to the external connection terminal 5 and another end 11e connected to the inspection pad 7. This reliably reduces the likelihood that the inspection member comes in contact with or is pressed against the first wires 6, the second wires 11, and the external connection terminals 5 and damages these components. This structure has higher flexibility in positioning the inspection pads 7. The inspection pads 7 can be positioned, for example, to be sufficiently separate from other components on the second surface 2b such as other wiring pads and wiring conductors and to be easily reachable by an inspection member. The display device 1 thus has higher reliability. In this case, each inspection pad 7 may have at least its central portion not overlapping the other end of the second wire 11. This structure reduces the likelihood that an inspection member such as an inspection terminal probe comes in contact with or is pressed against the second wire 11 adjacent to the inspection pad 7 and damages the second wire 11.

As illustrated in, for example, FIGS. 2 and 4, the inspection pads 7 may be positioned on an opposite side of the external connection terminals 5 from the first electrode pads 4. In this structure, the inspection pads 7 can be positioned to be sufficiently separate from the first electrode pads 4, the external connection terminals 5, and the first wires 6. This effectively reduces the likelihood of, for example, the electrode pads 4, the external connection terminals 5, or the first wires 6 being damaged during inspection, thus further improving the reliability of the display device 1.

As illustrated in FIG. 5, multiple inspection pads 7 may each include a first inspection pad 71 and a second inspection pad 72. The first inspection pad 71 and the second inspection pad 72 may be linearly in contact with the second wire 11 as described above and may be aligned in the direction in which the second wire 11 extends. This structure allows two inspection members to come in contact with the respective first and second inspection pads 71 and 72 to allow both the first and second inspection pads 71 and 72 to input high voltage or large current inspection signals stably into the pixel units 3p. With no other wiring pad, wiring conductor, or other components located adjacent to the other end 11e of the second wire 11, the first inspection pad 71 and the second inspection pad 72 may face each other across the other end 11e of the second wire 11.

A display device according to another embodiment of the present disclosure will now be described with reference to FIGS. 6 to 10. The display device illustrated in FIGS. 6 to 10 basically has the same or similar structure as the display device illustrated in FIGS. 1 to 5 except for the electrical connection between the inspection pads and the electrode pads. The same components will not be described in detail.

As illustrated in, for example, FIG. 6, the inspection pad 7 may be linearly in contact with the first wire 6 as described above for direct connection to the first wire 6. This structure reduces, for example, signal attenuation and any voltage drop between the inspection pad 7 and the first electrode pad 4, thus improving the inspection accuracy and thus the reliability of the display device 1.

The structure including the inspection pad 7 directly connected to the first wire 6 without using any second wire 11 may use a high-frequency inspection signal and can prevent a delay in the inspection signal and round edges of the waveform of the inspection signal that may be caused by, for example, the electrical resistance of the second wire 11 or by a parasitic capacitance between the second wire 11 and another wiring conductor in the display device 1. This allows the use of a high-frequency inspection signal, in addition to a direct current voltage or a low-frequency inspection signal, for various inspections, thus improving the reliability of the display device 1.

The inspection pad 7 having a polygonal shape such as a triangle, a rectangle, or a square may include one side that is entirely linearly in contact with the first wire 6 as illustrated in, for example, FIG. 6. This structure reduces the contact resistance between the inspection pad 7 and the first wire 6, thus effectively reducing, for example, signal attenuation and any voltage drop between the inspection pad 7 and the electrode pad 4. This can improve the inspection accuracy, and thus improve the reliability of the display device 1.

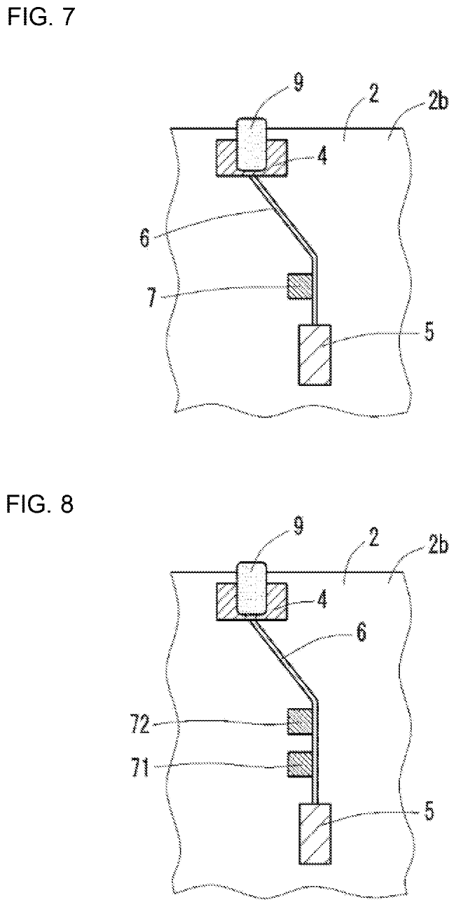

The inspection pad 7 may be connected directly to a portion of the first wire 6 closer to the external connection terminal 5 than to the first electrode pad 4 as illustrated in, for example, FIG. 7. The inspection pad 7 adjacent to the external connection terminal 5 that receives, for example, an input emission control signal or an input power supply voltage allows inspection to be performed under signal input conditions simulating the conditions in the display device 1 being a product. This further improves the reliability of the display device 1. In other words, various signals input from the external connection terminal 5 can have slight voltage drops due to the resistance of the first wire 6 while being transmitted through the first wire 6. With the inspection pad 7 connected to the portion of the first wire 6 closer to the first electrode pad 4 than to the external connection terminal 5, the inspection is performed with a signal with a voltage drop. Such voltage drops can vary based on the length and the width of each first wire 6. The inspection is thus performed under signal input conditions slightly different from the conditions in the display device 1 being a product.

As illustrated in FIG. 8, the same structure as in FIG. 7 may include multiple inspection pads 7 aligned in the direction in which the first wires 6 extend. The multiple inspection pads 7 may each include a first inspection pad 71 and a second inspection pad 72. The first inspection pad 71 and the second inspection pad 72 are linearly in contact with the first wire 6 as described above for direct connection to the first wire 6. This structure allows two inspection members to come in contact with the respective first and second inspection pads 71 and 72 to allow both the first and second inspection pads 71 and 72 to input high voltage or large current inspection signals stably into the pixel units 3p. This can improve the inspection accuracy, and thus improve the reliability of the display device 1.

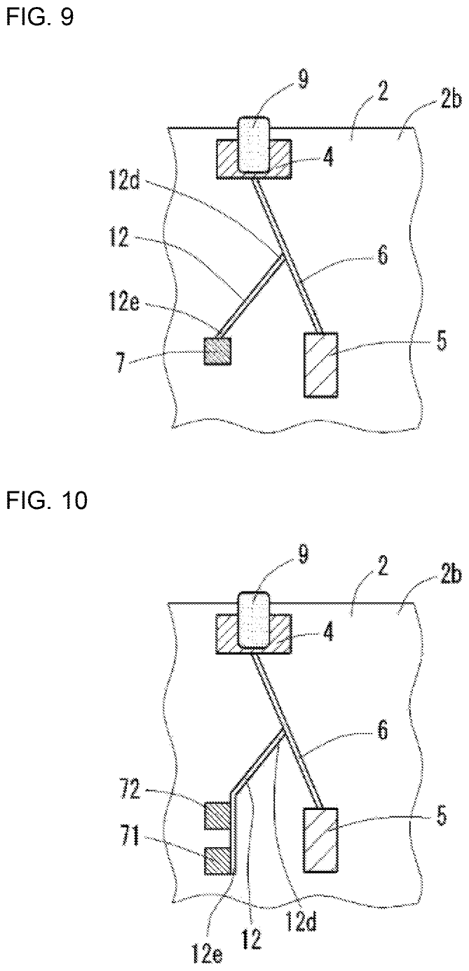

As illustrated in FIG. 9, the structure may include, on the second surface 2b, a third wire 12 including one end 12d connected to the first wire 6 and another end 12e connected to the inspection pad 7. This structure allows the length of wiring from the inspection pad 7 to the electrode pad 4 with the third wire 12 and the first wire 6 to be substantially equal to the length of wiring from the external connection terminal 5 to the electrode pad 4 with the first wire 6. This allows inspection to be performed under signal input conditions more precisely simulating the conditions in the display device 1 being a product, as described above. This further improves the reliability of the display device 1. The third wire 12 may include one end 12d connected to a middle of the first wire 6. This structure allows the length of wiring from the inspection pad 7 to the electrode pad 4 with the third wire 12 and the first wire 6 to be more precisely equal to the length of wiring from the external connection terminal 5 to the electrode pad 4 with the first wire 6. The length from one end of the first wire 6 to the middle of the first wire 6 to which one end 12d of the third wire 12 is connected may be about 40 to 60% or about 45 to 55% of the length of the first wire 6.

In the structure illustrated in FIG. 9, the inspection pad 7 may be positioned with at least its central portion not overlapping the other end of the third wire 12. This structure reduces the likelihood that an inspection member such as an inspection terminal probe comes in contact with or is pressed against the third wire 12 adjacent to the inspection pad 7 and damages the third wire 12.

As illustrated in FIG. 10, the same structure as in FIG. 9 may include multiple inspection pads 7 aligned in the direction in which the third wire 12 extends. The multiple inspection pads 7 may each include a first inspection pad 71 and a second inspection pad 72. The first inspection pad 71 and the second inspection pad 72 are connected to the first wire 6 with the third wire 12. The first inspection pad 71 and the second inspection pad 72 may be aligned in the direction in which the third wire 12 extends. This structure allows high voltage or large current inspection signals to be stably input into the pixel units 3p. This structure allows the length of wiring from the first inspection pad 71 to the first electrode pad 4 and the length of wiring from the second inspection pad 72 to the first electrode pad 4 to be substantially equal to the length of wiring from the external connection terminal 5 to the first electrode pad 4 with the first wire 6. This allows inspection to be performed under signal input conditions more precisely simulating the conditions in the display device 1 being a product, as described above. This further improves the reliability of the display device 1.

A display device according to another embodiment of the present disclosure will now be described with reference to FIGS. 11 and 12. In the embodiment described below, like reference numerals denote like structural components in the above embodiments. Such components will not be described in detail.

A display device 1 may include a substrate 2, a display 3, multiple first electrode pads 4, multiple external connection terminals 5, multiple first wires 6, and multiple inspection pads 7 as illustrated in, for example, FIGS. 11 and 12. The display 3 includes numerous pixel units 3p and is located on a first surface 2a of the substrate 2. In the display 3, the numerous pixel units 3p are arranged in a matrix in a first direction (lateral direction in FIG. 11) D1 and in a second direction (vertical direction in FIG. 11) D2 intersecting with the first direction D1 in a row direction. The first electrode pads 4 are located on a second surface 2b of the substrate 2. The first electrode pads 4 are electrically connected to pixel units 3p included in the columns of the display 3. As illustrated in, for example, FIGS. 11 and 12, each first electrode pad 4 is electrically connected to pixel units 3p with a side wire 9, a second electrode pad 8, and a first conductor pattern 10. The first electrode pads 4 may be located at the periphery of the second surface 2b and aligned in the first direction D1 in a plan view.

The external connection terminals 5 are located on the second surface 2b. The external connection terminals 5 are located in a central portion of the second surface 2b in a plan view. The external connection terminals 5 may be aligned in a first predetermined direction. The first predetermined direction may be the first direction D1 or a direction intersecting with the first direction D1. In the present embodiment, each external connection terminal 5 receives an emission control signal Sig that is input into multiple pixel units 3p electrically connected to the external connection terminal 5.

The first wires 6 are located on the second surface 2b. The first wires 6 are located between the first electrode pads 4 and the external connection terminals 5 in a plan view to connect the first electrode pads 4 and the external connection terminals 5 together.

The inspection pads 7 are located on the second surface 2b. The inspection pads 7 are electrically connected to the respective electrode pads 4. The inspection pads 7 may be electrically connected to the respective first electrode pads 4. The inspection pads 7 may be directly connected to the respective first electrode pads 4, may be directly connected to the respective external connection terminals 5, or may be directly connected to the respective first wires 6. Each inspection pad 7 may be connected to the first electrode pad 4, the external connection terminal 5, or the first wire 6 corresponding to the inspection pad 7 with a second wire 11 on the second surface 2b. In the present embodiment, each inspection pad 7 is connected to the connection terminal 5 corresponding to the inspection pad 7 with the second wire 11 on the second surface 2b as illustrated in, for example, FIG. 12.

The inspection pads 7 may be located in a central portion 2bp of the second surface 2b. This structure allows an inspection member in contact with the inspection pads 7 from the second surface 2b of the substrate 2 to apply a contact force uniformly to the entire second surface 2b easily. This reduces the likelihood that the substrate 2, for example, tilts or bends during inspection under the contact force. An area of the central portion 2bp may be at least 1% of the area of the second surface 2b. When the central portion 2bp has an area less than 10%, the substrate 2 is more likely to bend under the contact force concentrating on the central portion 2bp of the second surface 2b during inspection. The ratio of the area of the central portion 2bp to the area of the second surface 2b may be up to, for example, about 70%, about 60%, about 50%, or any other ratio.

The display device 1 may include an emission control signal line that can be inspected using an input electrical signal simulating an emission control signal Sig into the inspection pads 7.

The inspection pads 7 may be positioned on an opposite side of the external connection terminals 5 from the first electrode pads 4 as illustrated in, for example, FIG. 12. In other words, the inspection pads 7 may be in an area on the second surface 2b including neither the first electrode pads 4 nor the first wires 6 to have the external connection terminals 5 between the first electrode pads 4 and the first wires 6. This structure further reduces the likelihood of the first electrode pads 4 or the first wires 6 being damaged during inspection, thus further improving the reliability of the display device.

The inspection pads 7 may be arranged in a staggered manner as illustrated in, for example, FIG. 12. In other words, the inspection pads 7 may be connected to other ends of the second wires 11 that are arranged parallel to one another with alternate long lengths and short lengths. In this structure, adjacent inspection pads 7 have a longer distance between them, thus allowing an inspection member to easily come in contact with each inspection pad 7. This can improve the inspection accuracy, and thus improve the reliability of the display device 1. Each inspection pad 7 may not have the structure illustrated in FIG. 12, but may have any of the structures illustrated in FIGS. 4 to 10. The multiple first electrode pads 4 and the pixel units 3p electrically connected to the first electrode pads 4 may be electrically connected with the second electrode pads 8 and the side wires 9. Each second electrode pad 8 and multiple pixel units 3p may be electrically connected to each other with the first conductor pattern 10.

In the present embodiment, the display device 1 includes the inspection pads 7 on the second surface 2b opposite to the first surface 2a instead of being on the first surface 2a including the display 3 and thus can have a frame portion with a smaller area. The frame portions are thus less noticeable in a multi-display. The multi-display can have a uniform pixel pitch and thus have higher image quality and high definition. The display device 1 has higher flexibility in designing the positions, areas, and shapes of the multiple inspection pads 7. The display device 1 thus allows an inspection member to easily come in contact with the inspection pads 7. This reduces the likelihood of, for example, the electrode pads and the wiring conductors in the display device 1 being damaged during inspection, thus improving the inspection accuracy and the reliability of the display device 1.

Although the display device 1 can inspect the emission control signal line in the examples described above, the display device 1 may further inspect the power supply voltage line. The display device 1 may further include multiple electrode pads 4a, multiple external connection terminals 5a, multiple first wires 6a, and multiple inspection pads 7a as illustrated in, for example, FIGS. 11 and 12. The electrode pads 4a are located on the second surface 2b of the substrate 2. The electrode pads 4a may be made of the same conductive material as the electrode pads 4 in the same or similar manner. The electrode pads 4a are electrically connected to the numerous pixel units 3p included in the display 3. As illustrated in, for example, FIGS. 11 and 12, each electrode pad 4a is electrically connected to multiple pixel units 3p with a side wire 9a, a second electrode pad 8a, and a first conductor pattern 10a. The electrode pads 4a may be located at the periphery of the second surface 2b and aligned in the second direction D2 in a plan view.

The external connection terminals 5a are located on the second surface 2b. The external connection terminals 5a may be made of the same conductive material as the external connection terminals 5 in the same or similar manner. The external connection terminals 5a are located in a central portion of the second surface 2b in a plan view. The external connection terminals 5a may be aligned in a second predetermined direction. The second predetermined direction may be the second direction D2 or a direction intersecting with the second direction D2. The external connection terminals 5a include at least one first external connection terminal 5al and at least one second external connection terminal 5a2. The first power supply voltage Vdd to be provided to the display 3 is input into the first external connection terminal 5al. The second power supply voltage Vss to be provided to the display 3 is input into the second external connection terminal 5a2. The first power supply voltage Vdd may be an anode voltage of, for example, about 10 to 15 V. The second power supply voltage Vss may be lower than the first power supply voltage Vdd and may be a cathode voltage of, for example, about 0 to 3 V.

The first wires 6a are located on the second surface 2b. The first wires 6a may be made of the same conductive material as the first wires 6 in the same or similar manner. The multiple first wires 6a are located between the electrode pads 4a and the external connection terminals 5a in a plan view to connect the electrode pads 4a and the external connection terminals 5a together.

The inspection pads 7a are located on the second surface 2b. The inspection pads 7a may be made of the same conductive material as the inspection pads 7 in the same or similar manner. The inspection pads 7a are electrically connected to the respective first electrode pads 4a. The inspection pads 7a may be directly connected the respective electrode pads 4a, may be directly connected to the respective external connection terminals 5al and 5a2, and may be directly connected to the respective first wires 6a. The inspection pads 7a may be connected to the first electrode pads 4a, the external connection terminals 5a, or the first wires 6a corresponding to the inspection pads 7a with second wires 11a or third wires 12 (illustrated in FIG. 9) on the second surface 2b. In the present embodiment, the inspection pads 7a are connected to the external connection terminals 5al and 5a2 corresponding to the inspection pads 7a with the second wires 11a on the second surface 2b as illustrated in, for example, FIG. 12. The second wires 11a may be made of the same conductive material as the second wires 11 in the same or similar manner.

The display device 1 may include a power supply voltage line that can be inspected using an input inspection signal simulating the first power supply voltage Vdd to the inspection pads 7a connected to the first external connection terminals 5al and using an input inspection signal simulating the second power supply voltage Vss to the inspection pads 7a connected to the second external connection terminals 5a2.

The display device 1 may inspect the scanning signal line for selecting the pixel units 3p to write the emission control signal Sig and inspect the image signal line for inputting image signals into the pixel units 3p.

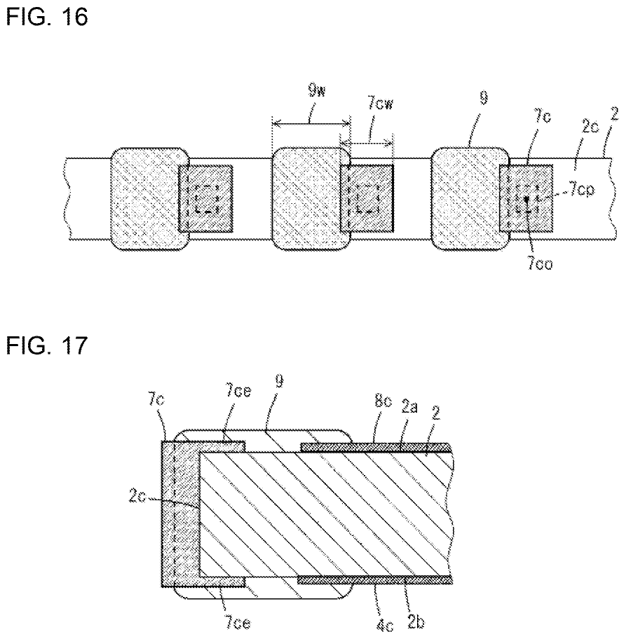

A display device according to another embodiment of the present disclosure will now be described with reference to FIGS. 15 to 17. FIG. 15 is a partial plan view of the display device according to the other embodiment of the present disclosure, illustrating its main part. FIG. 16 is a partial side view of the display device in FIG. 15, illustrating the main part. FIG. 17 is a partial cross-sectional view of the display device in FIG. 15, illustrating the main part. FIG. 16 illustrates inspection pads and side wires with hatching for ease of illustration.

In an embodiment of the present disclosure, a display device 1a illustrated in FIG. 15 includes a substrate 2 including a first surface 2a, side surfaces 2c, and a second surface 2b opposite to the first surface 2a, a display 3 on the first surface 2a, electrode pads 4 on the second surface 2b electrically connected to the display 3, side wires 9 extending from the first surface 2a to the second surface 2b through the side surfaces 2c and electrically connecting the display 3 and the electrode pads 4, and inspection pads 7c on the side surfaces 2c electrically connected to the side wires 9. At least a central portion 7cp (illustrated in FIG. 16) of each the inspection pad 7c does not overlap any side wire 9.

In one or more embodiments of the present disclosure, the display device 1a with the above structure produces the effects described below. With the inspection pads 7c on the side surfaces 2c of the substrate 2, the display device 1a can reduce the size of the frame portion or include no frame portion. This reduces the likelihood that the boundary portions between the display devices 1a in a multi-display are viewable to the viewer. This also reduces variations in the pixel pitch at the boundaries between the display devices 1a, thus easily achieving a uniform pixel pitch. The multi-display can thus have higher image quality and have high definition. The inspection pads 7c are positioned on the side surfaces 2c with at least their central portions 7cp not overlapping the side wires 9. This structure reduces the likelihood that an inspection member such as an inspection terminal probe comes in contact with or is pressed against the side wires 9 adjacent to the inspection pads 7c and damages the side wires 9. The display device 1a can thus be manufactured with a higher yield.

An area of the central portion 7cp of each inspection pad 7c may be at least 10% of the area of the inspection pad 7c. When the central portion 7cp has an area less than 10%, the side wire 9 is adjacent to a center 7co of the inspection pad 7c that comes in contact with or is pressed against an inspection member and may be damaged by the inspection member. The inspection member may come in contact with or is pressed against a larger area including the center 7co of the inspection pad 7c. When an area of the central portion 7cp of the inspection pad 7 is at least 10% of the area of the inspection pad 7, the side wire 9 is not too close to the center 7co. This reduces the likelihood of the inspection member damaging the side wire 9. The ratio of the area of the central portion 7cp to the area of the inspection pad 7c may be up to, for example, about 70%, about 60%, about 50%, or any other ratio.

As illustrated in FIG. 16, each inspection pad 7c may include an edge that is linearly in contact with a side wire 9. In this structure, each inspection pad 7c is directly connected to the side wire 9. This reduces connection resistance between the inspection pad 7c and the side wire 9, thus allowing accurate inspection with the inspection pad 7c. This also reduces the likelihood that an inspection member such as a terminal probe comes in contact with or is pressed against the side wires 9 adjacent to the inspection pads 7c and damages the side wires 9. The edges that are linearly in contact with each other may have, but are not limited to, a width of about 1 to 100 μm.

As illustrated in FIG. 16, the inspection pads 7c may each have a width 7cw smaller than a width 9w of the side wires 9. In this structure, the inspection pads 7c are easily located on the side surfaces 2c having a small area. For multiple side wires 9, an inspection pad 7c is easily arranged for each of the multiple side wires 9. A smaller pixel pitch also causes adjacent side wires 9 to be closer to each other. This structure also reduces the likelihood of short-circuiting between such two adjacent side wires 9. Each inspection pad 7c may have a width not less than 30% and less than 100% of the width of the side wire 9 (about 10 to 300 μm), but may have a width in another range of values.

The inspection pads 7c may have the same or similar structure as the structures in FIGS. 13B, 13C, and 13D. This structure produces the effects described above.

As illustrated in FIG. 17, each inspection pad 7c may include an extension 7ce extending toward at least one of the first surface 2a or the second surface 2b. In this structure, the inspection pad 7c and the side wire 9 have a larger area of contact between them. This reduces connection resistance between the inspection pad 7c and the side wire 9, thus allowing accurate inspection with the inspection pad 7c. This also improves the bonding force of the inspection pad 7c to the side surface 2c. The extension 7ce may have a length of, but not limited to, about 0.1 to 2 times the length of the body of the inspection pad 7c on the side surface 2c. Each side wire 9 is connected to a connection line 8c connected to a second electrode pad 8 on the first surface 2a of the substrate 2, and to a connection line 4c connected to a first electrode pad 4 on the second surface 2b of the substrate 2.

The inspection pad 7c may have the body on the side surface 2c thicker than the extension 7ce. This structure easily reduces the likelihood that the body of the inspection pad 7c is damaged by an inspection member such as an inspection terminal probe that comes in contact with or is pressed against the body of the inspection pad 7c. The inspection pad 7c may have the body with a thickness of, but not limited to, more than one time and not more than 10 times the thickness of the extension 7ce.

The inspection pads 7c may be covered with an overcoat layer of, for example, SiO₂, Si₃N₄, or a polymeric material such as an acrylic resin, similarly to the side wires 9. The inspection pads 7c in this structure are protected with the overcoat layer and are less likely to be, for example, damaged, chipped, and peeled. The overcoat layer covering the inspection pads 7c may be formed after the inspection using the inspection pads 7c is complete. The overcoat layer covering the side wires 9 may be used as the overcoat layer covering the inspection pads 7c. In this case, the overcoat layer may cover the entire surface of the side surfaces 2c.

The inspection pads 7 on the second surface 2b of the substrate 2 may also be covered with an overcoat layer. The overcoat layer covering the inspection pads 7 may be formed after the inspection using the inspection pads 7 is complete.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

In the embodiments of the present disclosure, the display device includes the inspection pads on the non-display surface of the display device. The display device can thus reduce the size of the frame portion or include no frame portion. This reduces the likelihood that the boundaries (frame portions) between the display devices in a multi-display are viewable to the viewer. This also reduces variations in the pixel pitch at the boundaries (frame portions) between the display devices, thus easily achieving a uniform pixel pitch. The multi-display can thus have higher image quality and have high definition. Each inspection pad is positioned on the second surface with at least its central portion not overlapping the first wire. This reduces the likelihood that an inspection member such as an inspection terminal probe comes in contact with or is pressed against, for example, the electrode pads and the wiring conductors adjacent to the inspection pads and damage, for example, the electrode pads, the wiring conductors, and the external connection terminals. The display device can thus be manufactured with a higher yield.

In the embodiments of the present disclosure, the display device includes the inspection pads on the side surfaces of the substrate. The display device can thus reduce the size of the frame portion or include no frame portion. This reduces the visibility of the boundaries between the display devices in a multi-display to the viewer. This also reduces variations in the pixel pitch at the boundaries between the display devices, thus easily achieving a uniform pixel pitch. The multi-display can thus have higher image quality and have high definition. Each inspection pad is positioned on the side surface with at least its central portion not overlapping the side wire. This reduces the likelihood that an inspection member such as an inspection terminal probe comes in contact with or is pressed against the side wires adjacent to the inspection pads and damage the side wires. The display device can thus be manufactured with a higher yield.

### INDUSTRIAL APPLICABILITY

The display device according to one or more embodiments of the present disclosure can be used in various electronic devices. Such electronic devices include automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, and guidance display devices installed at stations or airports.

### REFERENCE SIGNS

1, 1a display device
2 substrate
2a first surface
2b second surface
2bp central portion
2c side surface
3 display
3p pixel unit
31 light emitter
31a anode electrode
31b cathode electrode
32 electrode pad
32a anode pad
32b cathode pad
32c transparent conductive layer
4, 4a electrode pad (first electrode pad)
4c connection line
5, 5a external connection terminal
5al external connection terminal (first external connection terminal)
5a2 external connection terminal (second external connection terminal)
6, 6a first wire
7, 7a, 7c inspection pad
7o, 7co center
7p, 7cp central portion
71 first inspection pad
72 second inspection pad
8, 8a other electrode pad (second electrode pad)
8c connection line
81 connection wire
82 metal layer
83, 84, 85, 86, 87 insulating layer
88 transparent conductive layer
9, 9a side wire
10, 10a first conductor pattern
11, 11a second wire
11d one end
11e another end
12 third wire
12d one end
12e another end

1. A display device, comprising:
a substrate including a first surface, a side surface, and a second surface opposite to the first surface;
a display on the first surface;
an electrode pad on the second surface, the electrode pad being electrically connected to the display;
an external connection terminal on the second surface;
a first wire on the second surface, the first wire electrically connecting the electrode pad and the external connection terminal; and
an inspection pad on the second surface, the inspection pad being electrically connected to the electrode pad, and at least a central portion of the inspection pad not overlapping the first wire.

2. The display device according to claim 1, wherein
the inspection pad includes an edge linearly in contact with the first wire.

3. The display device according to claim 2, wherein
the inspection pad is connected to a portion of the first wire closer to the external connection terminal than to the electrode pad.

4. The display device according to claim 2, wherein
the display device includes a plurality of the inspection pads aligned in a direction in which the first wire extends.

5. The display device according to claim 1, wherein
an area of the central portion of the inspection pad is at least 10% of an area of the inspection pad.

6. The display device according to claim 1, wherein
no portion of the inspection pad overlaps the first wire.

7. The display device according to claim 6, further comprising:
a second wire on the second surface, the second wire including one end connected to the external connection terminal and another end connected to the inspection pad.

8. The display device according to claim 7, wherein
the inspection pad is positioned on an opposite side of the external connection terminal from the electrode pad.

9. The display device according to claim 7, wherein
the display device includes a plurality of the inspection pads aligned in a direction in which the second wire extends.

10. The display device according to claim 6, further comprising:
a third wire on the second surface, the third wire including one end connected to the first wire and another end connected to the inspection pad.

11. The display device according to claim 10, wherein
the display device includes a plurality of the inspection pads aligned in a direction in which the third wire extends.

12. The display device according to claim 6, wherein
the inspection pad is in a central portion of the second surface.

13. The display device according to claim 1, wherein
the electrode pad is at a periphery of the second surface.

14. The display device according to claim 1, further comprising:
another electrode pad on the first surface, the other electrode pad being electrically connected to the display; and
a side wire extending from the first surface through the side surface to the second surface and connecting the electrode pad and the other electrode pad.

15. The display device according to claim 1, wherein
the display includes a micro-light-emitting diode.

16. A display device, comprising:
a substrate including a first surface, a side surface, and a second surface opposite to the first surface;
a display on the first surface;
an electrode pad on the second surface, the electrode pad being electrically connected to the display;
a side wire extending from the first surface through the side surface to the second surface and electrically connecting the display and the electrode pad; and
an inspection pad on the side surface, the inspection pad being electrically connected to the side wire, and at least a central portion of the inspection pad not overlapping the side wire.

17. The display device according to claim 16, wherein
the inspection pad includes an edge linearly in contact with the side wire.

18. The display device according to claim 16, wherein
the inspection pad has a width smaller than a width of the side wire.

19. The display device according to claim 16, wherein
the inspection pad includes an extension extending toward at least one of the first surface or the second surface.
